(19) United States
(12) Patent Application Publication
(10) Pub. No.: US 2020/0059084 A1
(43) Pub. Date: Feb. 20, 2020

(54) SWITCH CIRCUIT AND POWER SOURCE DEVICE

(71) Applicants: AutoNetworks Technologies, Ltd., Yokkaichi, Mie (JP); Sumitomo Wiring Systems, Ltd., Yokkaichi, Mie (JP); Sumitomo Electric Industries, Ltd., Osaka-shi (JP)

(72) Inventors: Hideo Morioka, Yokkaichi, Mie (JP); Arinobu Nakamura, Yokkaichi, Mie (JP)

(21) Appl. No.: 16/348,324

(22) PCT Filed: Oct. 30, 2017
(86) PCT No.: PCT/JP2017/039070

§ 371 Date: May 8, 2019

(30) Foreign Application Priority Data
Nov. 15, 2016 (JP) 2016-222506

(51) Int. Cl. H02H 5/04; H02H 7/20; H02J 1/00; H03K 17/14; H01H 37/32; H02J 7/00

(52) U.S. Cl. CPC H02H 5/04; H02H 7/20; H02J 7/0024; H03K 17/145; H01H 37/32; H02J 1/00

(57) ABSTRACT

A switch circuit disposed on a wire that connects a plurality of batteries includes a semiconductor switch that switches the connection between the batteries to ON or to OFF, and a protective switch that is connected in parallel to the semiconductor switch. The protective switch has a pair of terminals that are each connected to the wire, and a conductive plate that is constituted by a plurality of conductive members having different thermal expansion coefficients being attached to each other. The conductive plate deforms with increasing temperature of the semiconductor switch and switches the connection between the terminals to ON.

### CROSS-REFERENCE TO RELATED APPLICATIONS

This application is the U.S. national stage of PCT/JP2017/039070 filed on Oct. 30, 2017, which claims priority of Japanese Patent Application No. JP 2016-222506 filed on Nov. 15, 2016, the contents of which are incorporated herein.

### TECHNICAL FIELD

The present disclosure relates to a switch circuit and a power source device.

### BACKGROUND

JP 2016-131138A discloses a protective circuit that has a conductive member provided on a substrate via a melting member, and when a semiconductor switch generates an abnormal amount of heat, the conductive member is displaced onto the substrate by the melting member melting, and comes in contact with two terminals provided on the substrate, thereby electrically connecting the terminals.

With the protective circuit disclosed in JP 2016-131138A, the terminals are electrically connected by the melting member melting, and therefore the temperature at which the terminals are connected is determined by the melting point of the melting member (temperature at which the protective circuit operates). However, it is not always possible to select a material with which an intended melting point can be realized. For example, if it is necessary to use lead-free solder for the melting member, then it is difficult to adjust the melting point and thus realizing a melting member with an intended melting point becomes a problem. Accordingly, it is not easy to appropriately set the protective circuit to operate at a certain temperature.

### SUMMARY

The present disclosure has been made in view of these circumstances and an object thereof is to provide a switch circuit and a power source device that include a protective circuit that operates at a certain temperature.

A switch circuit of the present disclosure is a switch circuit that is disposed on a wire that connects a plurality of power sources, and includes a semiconductor switch that is disposed on the wire and switches a connection between the plurality of the power sources to ON or to OFF, and a protective switch that is connected in parallel to the semiconductor switch and switches the connection between the power sources to ON by deforming with increasing temperature of the semiconductor switch.

A power source device of the present disclosure includes a plurality of power sources and the switch circuit described above.

### ADVANTAGEOUS EFFECTS OF DISCLOSURE

According to the present disclosure, it is possible to provide a switch circuit and a power source device that include a protective switch that operates at a certain temperature.

### BRIEF DESCRIPTION OF DRAWINGS

FIG. 1 is a block diagram showing an example of a configuration of a power source device according to a first embodiment.

FIG. 2A is a cross-sectional view showing an example of a configuration of a protective switch of the first embodiment.

FIG. 2B is a cross-sectional view showing an example of a configuration of the protective switch of the first embodiment.

FIG. 2C is a cross-sectional view showing an example of a configuration of the protective switch of the first embodiment.

FIG. 3A is a cross-sectional view showing an example of a configuration of the protective switch of a second embodiment.

FIG. 3B is a cross-sectional view showing an example of a configuration of the protective switch of the second embodiment.

FIG. 3C is a cross-sectional view showing an example of a configuration of the protective switch of the second embodiment.

### DETAILED DESCRIPTION OF PREFERRED EMBODIMENTS

First, embodiments of the present disclosure will be listed and described. Also, at least some parts of the embodiments described below may be combined as appropriate.

The switch circuit according to one embodiment of the present disclosure is disposed on a wire that connects a plurality of power sources, includes a semiconductor switch that is disposed on the wire and switches a connection between the plurality of power sources to ON or to OFF, and a protective switch that is connected in parallel to the semiconductor switch and switches the connection between the power sources to ON by deforming with increasing temperature of the semiconductor switch.

In the present embodiment, the protective switch, which is provided in parallel to the semiconductor switch, switches the connection between the power sources to ON by deforming with increasing temperature of the semiconductor switch. It is easier to set an operating temperature with a protective switch that switches the connection between the power sources to ON by deforming with increasing temperature, than with a configuration in which terminals are brought into contact by melting of a melting member. Accordingly, it is possible to realize a switch circuit that includes a protective switch that operates at a certain temperature.

A configuration is preferable in which the protective switch has a pair of terminals each connected to the wire, and a conductive plate that is constituted by a plurality of conductive members having different thermal expansion coefficients being attached to each other, wherein the conductive plate is connected to one terminal of the pair of terminals, and deforms so as to connect the one terminal and the other terminal of the pair of terminals with increasing temperature of the semiconductor switch.

In the present embodiment, the protective switch includes a conductive plate that is constituted by a plurality of conductive members having different thermal expansion coefficients being attached to each other. The conductive plate deforms with increasing temperature of the semiconductor switch, and the deformed conductive plate connects the terminals. It is easy to set the temperature at which a bi-metal, which is two types of thin metal films attached to each other, will deform, and thus a protective switch that operates at a certain temperature can be realized.

It is preferable that at least the other terminal of the pair of terminals is constituted by a melting member that is conductive and melts at a predetermined temperature.

In the present embodiment, a terminal to which the operated (deformed) protective switch connects is constituted by a melting member that melts at a predetermined temperature. Accordingly, it is possible to reduce the electrical resistance of the terminal of the melting member by the terminal melting when the predetermined temperature is reached.

A configuration is preferable in which, when the connection between the power sources is ON, the protective switch switches the connection between the power sources to OFF by deforming so as to return to an original shape with decreasing temperature of the semiconductor switch.

In the present embodiment, the operated protective switch switches the connection between power sources to OFF by deforming to its original shape with decreasing temperature of the semiconductor switch. Accordingly, if the temperature of the semiconductor switch falls due to the protective switch operating, the connection between the power sources by the protective switch is switched to OFF and the power sources are only connected by the semiconductor switch.

A configuration is preferable in which the protective switch switches the connection between the power sources to OFF at a temperature that is lower than the temperature when the protective switch switches the connection between the power sources to ON.

In the present embodiment, the protective switch switches the connection between power sources to OFF at a temperature that is lower than the temperature when the protective switch switches the connection between power sources to ON. Accordingly, once the power sources are connected by the protective switch, it is possible to prevent the connection between the power sources from frequently switching between ON and OFF because the connection between the power sources is maintained until the temperature thereof falls to the temperature at which the connection between the power sources is switched to OFF.

The power source device according to one embodiment of the present disclosure includes a plurality of power sources and any of the switch circuits described above.

In the present embodiment, the plurality of power sources are connected via a protective circuit that includes a protective switch that operates at a certain temperature.

Recent years have seen power source systems that include a plurality of batteries being installed in vehicles. Such systems are provided with a switch for switching the electrical connection of the batteries between ON and OFF. Because the switch provided between the batteries is frequently switched between ON and OFF, the switch may be a semiconductor relay (semiconductor switch) that has a longer switching lifetime than a mechanical relay. On the other hand, if a semiconductor switch is used, when an excessive current flows through the switch due to a short circuit or the like, the semiconductor element generates heat, and there is concern that the generated heat will damage the semiconductor element itself and peripheral components. For this reason, if a semiconductor switch is used, a configuration is provided in which the switch is switched to OFF before the temperature of the components that constitute the switch rises to the upper temperature limit of the components. Furthermore, a protective circuit is provided that protects the switch if the switch cannot be switched to OFF due to unforeseen circumstances. For example, the protective circuit is connected in parallel to the semiconductor switch and the current that flows to the semiconductor switch is reduced by the current that flows to the semiconductor switch being diverted to the protective circuit.

The following is a description of the switch circuit and power source device according to embodiments of the present disclosure, with reference to drawings that show the embodiments. Note that the present disclosure is not limited to these examples and is indicated by the claims, and all changes that come within the meaning and range of equivalency of the claims are intended to be embraced therein.

### First Embodiment

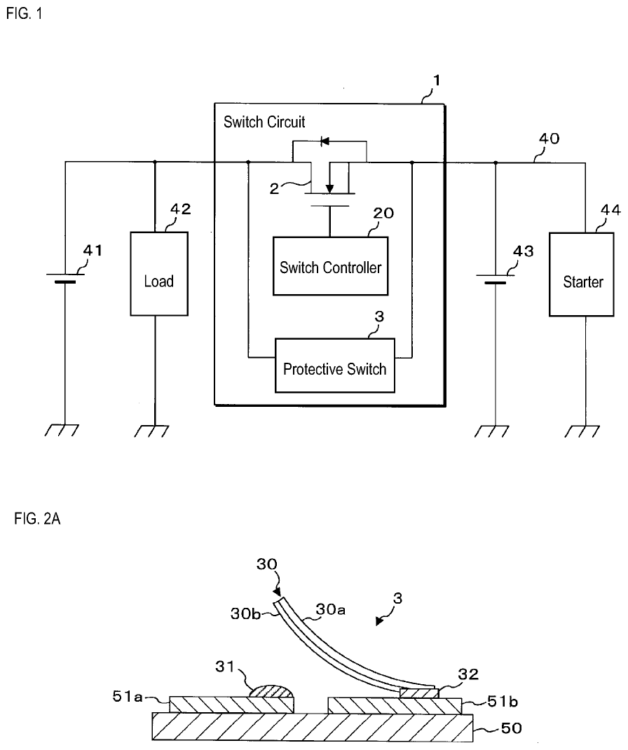

FIG. 1 is a block diagram showing an example of a configuration of a power source device according to a first embodiment. The power source device of the first embodiment is installed in a vehicle. Also, the power source device of the first embodiment includes two batteries (power sources), namely a first battery 41 and a second battery 43, and has a switch circuit 1 disposed on a wire 40 that connects the batteries 41 and 43. Note that the batteries 41 and 43 are connected in parallel via the switch circuit 1. The power source device installed in the vehicle may also have three or more batteries, in which case a switch circuit is disposed on the wires that connect each of the batteries.

In the power source device of the first embodiment, a load 42, which is an in-vehicle device such as a car navigation system, is connected in parallel to the first battery 41. Also, a starter 44 for starting an engine of the vehicle is connected in parallel to the second battery 43. Loads other than the load 42 and the starter 44 may also be connected in parallel to the first battery 41 and the second battery 43.

The switch circuit 1 includes a semiconductor switch 2 that is disposed on the wire 40 and switches the connection between the batteries 41 and 43 between ON and OFF, a switch controller 20 that controls the switching of the semiconductor switch 2 between ON and OFF, and a protective switch 3 that is connected in parallel to the semiconductor switch 2. FIG. 1 shows an example in which the semiconductor switch 2 is constituted by an N-channel FET (Field Effect Transistor), but the semiconductor switch 2 can also be constituted by a P-channel FET.

The switch controller 20 switches the semiconductor switch 2 to OFF when the connection between the first battery 41 and the second battery 43 is to be disconnected. For example, a notification signal is input to the switch controller 20 in advance when the starter 44 starts the engine. When this notification signal is input, the switch controller 20 switches the semiconductor switch 2 to OFF and disconnects the connection between the first battery 41 and the second battery 43.

The starter 44 requires a large amount of electrical current when starting the engine, and therefore a large voltage fluctuation occurs when the engine is started. Accordingly, in order to stop the voltage fluctuation that occurs on the starter 44 (second battery 43) side from affecting the first battery 41 and the load 42, the connection between the first battery 41 and the second battery 43 is disconnected immediately before the engine is started by the starter 44 as described above.

After the voltage of the second battery 43 recovers, the switch controller 20 switches the semiconductor switch 2 to ON, and resumes the connection between the first battery 41 and the second battery 43. Note that, normally, the semiconductor 2 is switched to ON by the switch controller 20, and thus the load 42 and the like are normally supplied with power from the two batteries 41 and 43.

In the power source device of the first embodiment, for example, when a short circuit occurs in the second battery 43 side, a large current flows from the first battery 41 to the semiconductor switch 2 through the short circuit path. If a large current flows to the semiconductor switch 2, the semiconductor element that constitutes the semiconductor switch 2 generates heat, and there is concern that the semiconductor element itself and peripheral components will overheat and the components will be damaged.

In view of this, with the power source device of the first embodiment, the protective switch 3 operates before the components overheat, and a connection between the batteries 41 and 43 via the protective switch 3 is switched to ON. If the protective switch 3 is operated, the large current that flows to the semiconductor switch 2 is diverted to the protective switch 3 and thus the current that flows through the semiconductor switch 2 can be reduced. As a result, the heating of the semiconductor element is suppressed, and damage to the components can be prevented.

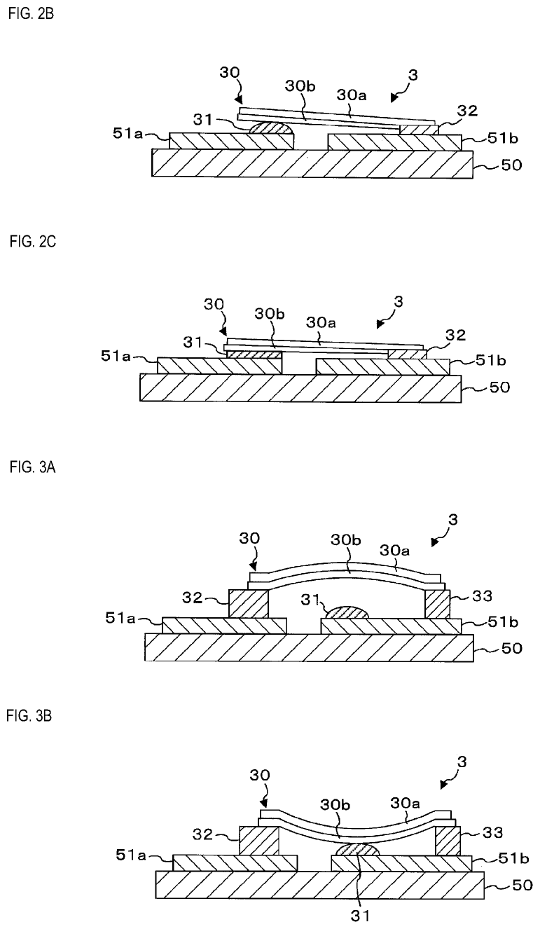

FIGS. 2A to 2C are cross-sectional views showing an example of the configuration of the protective switch 3 of the first embodiment. FIG. 2A shows the protective switch 3 in an OFF state (non-operating state), while FIGS. 2B and 2C show the protective switch 3 in an ON state (operating state).

The protective switch 3 of the first embodiment is provided with bus bars 51a and 51b that are formed apart from each other on a substrate 50. The bus bars 51a and 51b are constituted by a conductive material and the wire 40 is connected to both of the bus bars 51a and 51b. For example, in the wire 40 shown in FIG. 1, the wire 40 that is connected to the left hand side of the switch circuit 1 is connected to the bus bar 51a, and the wire 40 that is connected to the right hand side of the switch circuit 1 is connected to the bus bar 51b. In such a configuration, the connection between the batteries 41 and 43 via the wire 40 can be switched to ON or to OFF by the protective switch 3 switching the connection between the bus bars 51a and 51b to ON or to OFF. Note that the semiconductor switch 2 may be provided so as to switch the connection between the bus bars 51a and 51b to ON or to OFF.

Specifically, the protective switch 3 includes a first terminal 31 that is provided on an upper surface of the bus bar 51a, a second terminal 32 that is provided on an upper surface of the bus bar 51b, and a rectangular conductive plate 30 that is fixed to (connected to) one end of the second terminal 32. The first terminal 31 and the second terminal 32 (pair of terminals) are formed from a conductive material and are connected to the wire 40 via the bus bars 51a and 51b, respectively.

The conductive plate 30 is formed from a bi-metal that is constituted by two thin metal films (conductive members) 30a and 30b having different thermal expansion coefficients being attached to each other. The conductive plate 30 is mounted to the substrate 50 (bus bar 51b) with only one end connected to the second terminal 32, and as shown in FIG. 2A, the other end of the conductive plate 30 is normally not connected to the first terminal 31. Specifically, normally, the protective switch 3 is in an OFF state (non-operating state), and the first terminal 31 and the second terminal 32 are not electrically connected.

The conductive plate 30 is configured to deform with increasing ambient temperature, and, in the first embodiment, is configured to deform from a curved shape as shown in 2A to a linear shape as shown in FIGS. 2B and 2C. The conductive plate 30 shown in FIGS. 2A to 2C is, for example, mounted with the thin metal film 30a, which has a large thermal expansion coefficient, on the upper side.

The protective switch 3 is switched to ON (operating state), which is a state in which the connection between the batteries 41 and 43 is switched to ON by the conductive plate 30 deforming and the other end of the conductive plate 30 connecting with the first terminal 31. Accordingly, the temperature at which the conductive plate 30 deforms need only be set such that the protective switch 3 operates before the semiconductor switch 2 overheats according to the specifications of the semiconductor switch 2. Note that the conductive plate 30 may be constituted by the thin metal films 30a and 30b that are made from an iron or nickel alloy that has manganese, chromium, copper, or the like added thereto, and the temperature at which the conductive plate 30 deforms can be appropriately set by the content of the material or materials of the thin metal films 30a and 30b. Also, it is also possible to adjust the temperature at which the other end of the conductive plate 30 connects with the first terminal 31 by adjusting the initial shape thereof. Note that it is preferable to dispose the protective switch 3 in the vicinity of the semiconductor switch 2 so that the ambient temperature of the protective switch 3 is close to the temperature of the semiconductor switch 2.

With protective switch 3 as configured above, the conductive plate 30 will deform with increasing temperature of the semiconductor switch 2 if, for example, the semiconductor switch 2 (semiconductor element) generates an abnormal amount of heat due to a large current flowing to the semiconductor switch 2. Thus, as shown in FIG. 2B, at the point in time at which the other end of the conductive plate 30 comes into contact with the first terminal 31, the protective switch 3 switches ON (operates). If the protective switch 3 operates, the large current that flows to the semiconductor switch 2 will be diverted to the protective switch 3, and therefore the current flowing through the semiconductor switch 2 will decrease and overheating of the semiconductor element and peripheral components can be avoided.

If the current flowing to the semiconductor switch 2 decreases, the temperature of the semiconductor switch 2 (semiconductor element) falls. Accordingly, when the protective switch 3 is operating, the conductive plate 30 deforms back to its original shape with decreasing temperature of the semiconductor switch 2. Specifically, the shape of the conductive plate 30 as shown in FIG. 2B deforms to the shape shown in FIG. 2A. Thus, at the point in time at which the other end of the conductive plate 30 separates from the first terminal 31 as shown in FIG. 2A, the protective switch 3 switches to an OFF state in which the connection between the batteries 41 and 43 is switched to OFF, and returns to its usual state.

The thin metal films 30a and 30b that constitute the conductive plate 30 and the first terminal 31 and the second terminal 32 are preferably constituted by a conductive material that has a low electrical resistance. With this, it is possible to further reduce the current that flows to the semiconductor switch 2 when the protective switch 3 is operated. Also, one end of the conductive plate 30 and the second terminal 32 may be fixed together with use of solder, a screw, or the like. It is preferable that a member constituted by a conductive material with a low electrical resistance is used to fix the one end of the conductive plate 30 to the second terminal 32.

The first terminal 31 may also be constituted by a melting member that melts at a predetermined temperature. For example, the first terminal 31 can be constituted by a melting member that melts at a temperature that is higher than the temperature at which the protective switch 3 operates (that is, the temperature at which the conductive plate 30 deforms). In this case, if the temperature of the semiconductor switch 2 (semiconductor element) rises further after the protective switch 3 switches to ON as shown in FIG. 2B and reaches the melting temperature of the first terminal 31, the first terminal 31 melts as shown in FIG. 2C. A solder, for example, can be used as the melting member, in which case the electrical resistance of the first terminal 31 will decrease after the melting member has melted. If the semiconductor switch 2 generates enough heat to melt the melting member (first terminal 31), it is unlikely that the semiconductor switch 2 will be restored. Accordingly, if conditions arise that melt the first terminal 31, the current that flows to the semiconductor switch 2 can be further reduced by further reducing the electrical resistance of the first terminal 31. Note that if the temperature of the semiconductor switch 2 lowers after the first terminal 31 has melted and the first terminal 31 solidifies, the other end of the conductive plate 30 and the first terminal 31 will be connected by the solidified melting member (first terminal 31), and therefore the ON state of the protective switch 3 will be maintained. Accordingly, in this case, the connection between the batteries 41 and 43 via the protective switch 3 can be maintained rather than only via the semiconductor switch 2, which is unlikely to be restored, and therefore the power source device can operate as usual. Note that if solder solidifies after melting, the solder becomes low resistant, and is thus preferable to use as the melting member.

In the first embodiment, the protective switch 3 is constituted by the conductive plate 30 that is made from a bi-metal. Bi-metal can be adjusted to deform at a certain temperature, and therefore it can be used to easily realize the protective switch 3 that operates at a certain temperature. Accordingly, the protective switch 3 can be configured appropriately for the environment in which it will be disposed, and it becomes possible to install the switch circuit 1 and power source device provided with an appropriate protective switch 3.

Note that the conductive plate 30 is not limited to a configuration that uses a bi-metal of two types of thin metal films 30a and 30b attached to each other. Three or more thin metal films may also be attached to each other to constitute the conductive plate 30, or one type of thin metal film, such as a shape-memory alloy, may also be used to constitute the conductive plate 30, as long as the thin metal film to be used deforms at a certain temperature.

### Second Embodiment

The power source device of a second embodiment has a configuration similar to that of the power source device of the first embodiment, with the exception of the configuration of the protective switch 3, and therefore the same reference numerals will be assigned for similar configurations and descriptions thereof will be omitted.

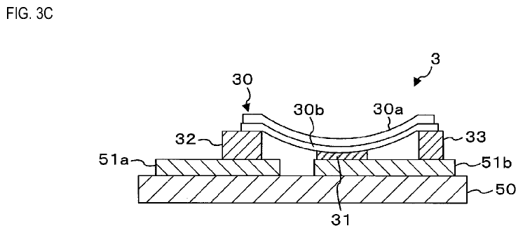

FIGS. 3A to 3C are cross-sectional views showing an example of the configuration of the protective switch 3 of the second embodiment. FIG. 3A shows the protective switch 3 in an OFF state (non-operating state), while FIGS. 3B and 3C show the protective switch 3 in an ON state (operating state). Note that the same reference numerals and names will also be assigned to configurations of the protective switch 3 that are similar to the first embodiment.

The protective switch 3 of the second embodiment is also provided between the bus bars 51a and 51b, which are formed on the substrate 50. The protective switch 3 of the second embodiment includes the first terminal 31 that is provided on the upper surface of the bus bar 51b, the second terminal 32 that is provided on the upper surface of the bus bar 51a, and the conductive plate 30. The protective switch 3 of the second embodiment includes, on the upper surface of the bus bar 51b, an insulating support body 33 that is constituted by an insulating material and is positioned facing the second terminal 32 with the first terminal 31 located therebetween. As shown in FIG. 3A, the conductive plate 30 of the second embodiment has a curved rectangular plate shape, with one end fixed to the second terminal 32 and the other end fixed to the insulating support body 33, and is mounted to the substrate 50 (bus bars 51a and 51b) in an upward curving state. Accordingly, one end of the conductive plate 30 is electrically connected to the wire 40 via the second terminal 32 and the bus bar 51a, but the other end of the conductive plate 30 is not electrically connected to the first terminal 31 or the bus bar 51b (wire 40). Specifically, the protective switch 3 is normally in an OFF state (non-operating state) and the first terminal 31 and the second terminal 32 are not electrically connected.

The conductive plate 30, the first terminal 31, and the second terminal 32 respectively have similar configurations to the conductive plate 30, the first terminal 31, and the second terminal 32 of the first embodiment. It is preferable that the second terminal 32 and one end of the conductive plate 30 and are fixed together with use of solder or a screw, and that the fixing member thereof is constituted by a conductive material that has a low electrical resistance.

The conductive plate 30 of the second embodiment is configured to have both ends fixed to the second terminal 32 and the insulating support body 33, and therefore is configured to deform from an upward curving shape as shown in FIG. 3A to a downward curving shape as shown in FIGS. 3B and 3C. Note that the conductive plate 30 can deform in such a way by mounting the conductive plate 30 with the thin metal film 30a having a large thermal expansion coefficient on the upper side.

With the protective switch 3 configured as above, if the semiconductor switch 2 (semiconductor element) generates an abnormal amount of heat, the conductive plate 30 will deform with increasing temperature of the semiconductor switch 2, and the protective switch 3 will switch to ON (operate) at the point in time at which the lower surface conductive plate 30 (thin metal film 30b) comes into contact with the first terminal 31 as shown in FIG. 3B. Through this, the first terminal 31 and the second terminal 32 are connected, and the connection between the batteries 41 and 43 is switched to ON. In the second embodiment also, if the protective switch 3 operates, the large current that flows to the semiconductor switch 2 will be diverted to the protective switch 3, and therefore the current that flows through the semiconductor switch 2 will decrease and overheating of the semiconductor element can be avoided.

Also, when the protective switch 3 is operating, if the temperature of the semiconductor switch 2 falls, the conductive plate 30 will deform back to its original shape, and the protective switch 3 switches to OFF and returns to its normal state at the point in time at which the lower surface of the conductive plate 30 separates from the first terminal 31 as shown in FIG. 3A.

With the protective switch 3 of the second embodiment, the amount of energy required for the conductive plate 30 to deform from the shape shown in FIG. 3A to the shape shown in FIG. 3B is different to the amount of energy required for the conductive plate 30 to deform from the shape shown in FIG. 3B to the shape shown in FIG. 3A. Accordingly, by appropriately setting the thermal expansion coefficients of the thin metal films 30a and 30b, a configuration is possible in which the temperature at which the protective switch 3 switches from ON to OFF is lower than the temperature at which the protective switch 3 switches from OFF to ON. By doing so, it is possible to prevent the protective switch 3 from frequently switching between ON and OFF.

Also, with the protective switch 3 of the second embodiment, as shown in FIG. 3A, the conductive plate 30 is curved and both ends thereof are fixed to the second terminal 32 and the insulating support body 33. Accordingly, if the semiconductor switch 2 generates an abnormal amount of heat, the thin metal film 30a having a large thermal expansion coefficient presses the thin metal film 30b downward, and if the pushing force from the thin metal film 30a becomes greater than or equal to a predetermined value, the conductive plate 30 will deform to the state as shown in FIG. 3B. Specifically, hysteresis can be created in the protective switch 3, and this deformation utilizes a phenomenon referred to as buckling.

In the second embodiment also, the first terminal 31 can be constituted by a melting member that melts at a predetermined temperature (a temperature higher than the temperature at which the protective switch 3 operates). In this case, if the temperature of the semiconductor switch 2 (semiconductor element) rises further after the protective switch 3 switches to ON as shown in FIG. 3B and reaches the melting temperature of the first terminal 31, the first terminal 31 melts as shown in FIG. 3C. If solder is used as the melting member, it is possible to further decrease the electrical resistance of the first terminal 31, when the semiconductor switch 2 is unlikely to be restored, by melting the first terminal 31 (melting member).

Also, if the temperature of the semiconductor switch 2 falls after the first terminal 31 has melted and the first terminal 31 solidifies, the lower surface of the conductive plate 30 and the first terminal 31 will be connected by the solidified melting member (the first terminal 31) and therefore the ON state of the protective switch 3 can be maintained.

Effects similar to those of the switch circuit 1 of the first embodiment can be obtained with the switch circuit 1 of the second embodiment. Also, in the second embodiment, the conductive plate 30 need not be constituted by a bi-metal, and may also be constituted by three or more types of thin metal films being attached to each other, or may also constituted by one type of thin metal film such as a shape-memory alloy.

The embodiments disclosed in this application are to be considered in all respects as illustrative and not restrictive. The scope of the present disclosure is indicated by the claims rather than by the meaning of the above description, and all changes that come within the meaning and range of equivalency of the claims are intended to be embraced therein.

1. A switch circuit disposed on a wire that connects a plurality of power sources, the switch circuit comprising:
a semiconductor switch that is disposed on the wire and switches a connection between the plurality of power sources to ON or to OFF; and
a protective switch that is connected in parallel to the semiconductor switch and switches the connection between the power sources to ON by deforming with increasing temperature of the semiconductor switch.

2. The switch circuit according to claim 1, wherein the protective switch has:
a pair of terminals that are each connected to the wire; and
a conductive plate that is constituted by a plurality of conductive members having different thermal expansion coefficients being attached to each other,
wherein the conductive plate is connected to one terminal of the pair of terminals, and deforms so as to connect the one terminal and the other terminal of the pair of terminals with increasing temperature of the semiconductor switch.

3. The switch circuit according to claim 2, wherein at least the other terminal of the pair of terminals is constituted by a melting member that is conductive and melts at a predetermined temperature.

4. The switch circuit according to claim 1, wherein, when the connection between the power sources is ON, the protective switch switches the connection between the power sources to OFF by deforming so as to return to an original shape with decreasing temperature of the semiconductor switch.

5. The switch circuit according to claim 4, wherein the protective switch switches the connection between the power sources to OFF at a temperature that is lower than the temperature when the protective switch switches the connection between the power sources to ON.

6. A power source device comprising:
a plurality of power sources; and
the switch circuit according to claim 1.

7. The switch circuit according to claim 2, wherein, when the connection between the power sources is ON, the protective switch switches the connection between the power sources to OFF by deforming so as to return to an original shape with decreasing temperature of the semiconductor switch.

8. The switch circuit according to claim 3, wherein, when the connection between the power sources is ON, the protective switch switches the connection between the power sources to OFF by deforming so as to return to an original shape with decreasing temperature of the semiconductor switch.

9. A power source device comprising:
a plurality of power sources; and
the switch circuit according to claim 2.

10. A power source device comprising:
a plurality of power sources; and
the switch circuit according to claim 3.

11. A power source device comprising:
a plurality of power sources; and
the switch circuit according to claim 4.

12. A power source device comprising:
a plurality of power sources; and
the switch circuit according to claim 5.
